(19) United States
(12) Patent Application Publication
(10) Pub. No.: US 2009/0315058 A1
(43) Pub. Date: Dec. 24, 2009

(54) NITRIDE SEMICONDUCTOR LIGHT EMITTING DEVICE AND METHOD OF MANUFACTURING THE SAME

(75) Inventors: Jin Bock LEE, Osan (KR); Ho Young Song, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS, CO., Gyunggi-Do (KR)

(21) Appl. No.: 12/546,896

(22) Filed: Aug. 25, 2009

Related U.S. Application Data
(62) Division of application No. 11/907,564, filed on Oct. 15, 2007.

(30) Foreign Application Priority Data
Oct. 27, 2006 (KR) 10-2006-0105230

(51) Int. Cl. H01L 33/00

(52) U.S. Cl. 257/98; 438/29; 257/99; 438/46; 257/E33.068; 257/E33.013

(57) ABSTRACT

There are provided a nitride semiconductor light emitting device and a method of manufacturing the same, the device including: a first conductivity type nitride semiconductor layer formed on a substrate; an active layer formed on the first conductivity type nitride semiconductor layer; a second conductivity type nitride semiconductor layer formed on the active layer; a light-transmitting low refractive index layer formed on the second conductivity type nitride semiconductor layer, the light-transmitting low refractive index layer having a plurality of openings through which the second conductivity type nitride semiconductor layer is partially exposed and formed of a material having a refractive index lower than a refractive index of the second conductivity type nitride semiconductor layer; and a high conductivity ohmic contact layer formed on the light-transmitting low refractive index layer and connected to the second conductivity type nitride semiconductor layer through the openings of the light-transmitting low refractive index layer.

### CLAIM OF PRIORITY

This application claims the benefit of Korean Patent Application No. 2006-0105230 filed on Oct. 27, 2006, in the Korean Intellectual Property Office, the disclosure of which is incorporated herein by reference.

### BACKGROUND OF THE INVENTION

1. Field of the Invention

The present invention relates to a nitride semiconductor light emitting device and a method of manufacturing the same, and more particularly, to a nitride semiconductor light emitting device capable of mitigating degradation of light extraction effect due to a reflecting surface of a light emitting diode and a method of manufacturing the same.

2. Description of the Related Art

Highly efficient, excellent in color reproduction, environmentally-friendly and semi-permanent, semiconductor light emitting devices are widely used for mobile phones, cameras, liquid crystal display televisions (LCD TVs) and the like. In addition, studies have been conducted to expand its application to illumination. However, to reach a capacity of the current illumination, which is 80 lm/W (fluorescent lamp) a higher efficiency is required from LED.

The efficiency of LED is distinguished between internal quantum efficiency and extraction efficiency, and for example, the internal quantum efficiency may be increased by improving the quality of an active layer by epitaxial growth techniques and the extraction efficiency may be improved through a manufacturing and packaging process. In this case, the extraction efficiency represents a ratio of the photons emitted externally to the photons generated from electron-hole recombination.

FIG. 1 is a side cross-sectional view illustrating a conventional flip-chip nitride semiconductor light emitting device including a substrate 11, and a first nitride semiconductor layer 12, an active layer 13 and a second nitride semiconductor layer 14 sequentially formed on the substrate 11. The substrate 11 of the light emitting device is a light-transmitting substrate such as a sapphire substrate and thus may be utilized as a light emitting surface.

Of first and second electrodes 15 and 16 of the nitride semiconductor light emitting device, the p-electrode 15 in particular not only forms an ohmic contact with the second nitride semiconductor layer 14, which may be a p-type nitride semiconductor layer, but also is required to have a high reflectance for reflecting the light emitted from the active layer 13 to the sapphire substrate 11.

However, the p-type nitride semiconductor layer 14 is highly resistant and thus formed of a very thin layer, and is adjacent to the reflecting surface. Thus, the light emitted from the active layer 13 may not be emitted out of the chip but guided and totally reflected inside the chip to disappear eventually, due to the difference in refractive indices between the p-type nitride semiconductor and the reflecting surface. Even if the light is emitted out of the chip, a significant amount of energy loss is induced.

As described above, when the reflecting surface is formed on an entire surface, its effect is significant and considerably contributes to degradation in extraction. Therefore, a new solution is required to improve the light extraction efficiency to a maximum in the art.

### SUMMARY OF THE INVENTION

An aspect of the present invention provides a nitride semiconductor light emitting device capable of mitigating degradation of extraction due to a reflecting surface in a semiconductor light emitting device and a method of manufacturing the same.

According to an aspect of the invention, there is provided a nitride semiconductor light emitting device including: a first conductivity type nitride semiconductor layer formed on a substrate; an active layer formed on the first conductivity type nitride semiconductor layer; a second conductivity type nitride semiconductor layer formed on the active layer; a light-transmitting low refractive index layer formed on the second conductivity type nitride semiconductor layer, the light-transmitting low refractive index layer having a plurality of openings through which the second conductivity type nitride semiconductor layer is partially exposed and formed of a material having a refractive index lower than a refractive index of the second conductivity type nitride semiconductor layer; and a high reflectivity ohmic contact layer formed on the light-transmitting low refractive index layer and connected to the second conductivity type nitride semiconductor layer through the openings of the light-transmitting low refractive index layer.

According to another aspect of the invention, there is provided a method of manufacturing a nitride semiconductor light emitting device, the method including: forming a first conductivity nitride semiconductor layer on a substrate; forming an active layer on the first conductivity type nitride semiconductor layer; forming a second conductivity type nitride semiconductor layer on the active layer; forming a light-transmitting low refractive index layer, formed of a material having a refractive index lower than a refractive index of the second conductivity type nitride semiconductor layer, on the second conductivity type nitride semiconductor layer; forming a plurality of openings in the light-transmitting low refractive index layer to partially expose the second conductivity type nitride semiconductor layer; and forming a high reflectivity ohmic contact layer on the light-transmitting low refractive index layer such that the high reflectivity ohmic contact layer is connected to the second conductivity type nitride semiconductor layer through the openings of the light-transmitting low refractive index layer.

According to another still another aspect of the invention, there is provided a nitride semiconductor light emitting device including: a first conductivity type nitride semiconductor layer formed on a substrate; an active layer formed on the first conductivity type nitride semiconductor layer; a second conductivity type nitride semiconductor layer formed on the active layer; a high reflectivity ohmic contact layer formed on the second conductivity type nitride semiconductor layer; and a plurality of vacant structures having a refractive index lower than a refractive index of the second conductivity type nitride semiconductor layer and formed at least one of inside the second conductivity type nitride semiconductor layer and between the high reflectivity ohmic contact layer and the second conductivity type nitride semiconductor layer.

The plurality of vacant structures may be formed in an area between the high reflectivity ohmic contact layer and the second conductivity type nitride semiconductor layer.

The device may further include a conductive material layer formed on the second conductivity type nitride semiconductor layer, between the high reflectivity ohmic contact layer and the second conductivity type nitride semiconductor layer, and having a plurality of openings, wherein the plurality of openings are provided as the plurality of vacant structures by the high reflectivity ohmic contact layer formed on the conductive material layer.

The plurality of vacant structures may be formed inside the second conductivity type nitride semiconductor layer.

The plurality of vacant structures may be obtained by forming a plurality of pits in a lower region of the second conductivity type nitride semiconductor layer and re-growing an upper region of the second conductivity type semiconductor layer such that the pits are retained as the vacant structures. In this case, the plurality of vacant structures may be irregular in size and arrangement.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side cross-sectional view Illustrating a conventional nitride semiconductor light emitting device;

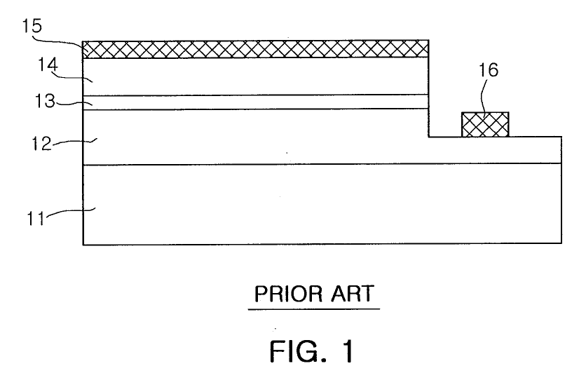

FIG. 2 is a side cross-sectional view illustrating a nitride semiconductor light emitting device according to an exemplary embodiment of the present invention;

FIGS. 3A to 3C are views illustrating a method of manufacturing the nitride semiconductor light emitting device shown in the embodiment of FIG. 2;

FIG. 4 is a side cross-sectional view illustrating a nitride semiconductor light emitting device according to another exemplary embodiment of the present invention;

FIGS. 5A to 5C are views illustrating a method of manufacturing the nitride semiconductor light emitting device shown in the embodiment of FIG. 4;

FIG. 6 is a side cross-sectional view illustrating a nitride semiconductor light emitting device according to further another embodiment of the present invention;

FIGS. 7A to 7D are views illustrating a method of manufacturing the nitride semiconductor light emitting device shown in the embodiment of FIG. 6;

FIG. 8 is a side cross-sectional view illustrating a nitride semiconductor light emitting device according to still another embodiment of the present invention; and

FIG. 9 is a graph comparing the conventional light emitting device with the light emitting device according to the present invention.

### DETAILED DESCRIPTION OF THE PREFERRED EMBODIMENT

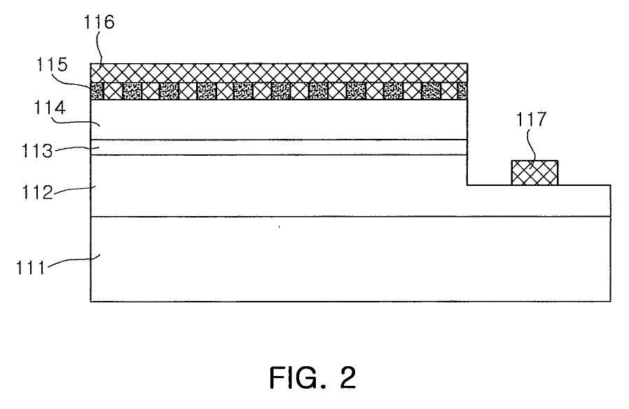

A nitride semiconductor light emitting device and a method of manufacturing the same according to an exemplary embodiment of the present invention will now be described in detail with reference to FIGS. 2 to 9.

FIG. 2 is a side cross-sectional view illustrating a nitride semiconductor light emitting device according to an exemplary embodiment of the present invention.

First, as shown in FIG. 2, the nitride semiconductor light emitting device includes a first conductivity type nitride semiconductor layer 112 formed on a substrate 111, an active layer 113 formed on the first conductivity type nitride semiconductor layer 112, a second conductivity type nitride semiconductor layer 114 formed on the active layer 113, a light-transmitting low refractive index layer 115 formed on the second conductivity type nitride semiconductor layer 114, and a high reflectivity ohmic contact layer 116 formed on the light-transmitting low refractive index layer 115.

The substrate 111 is suitable for growing nitride semiconductor single crystals, and may be a heterogeneous substrate like a sapphire substrate and a SiC substrate or a homogenous substrate like a nitride substrate.

The light-transmitting low refractive index layer 115 is formed of a material having a refractive index lower than a refractive index of the second conductivity type nitride semiconductor layer 114, and has a plurality of openings through which the second conductivity type nitride semiconductor layer 114 is partially exposed.

The light-transmitting low refractive index layer 115 may reflect the light generated from the active layer 113 before the light partially reaches the high reflectivity ohmic contact layer 116 by using the difference in refractive indices with GaN. This mechanism serves to compensate the high reflectivity ohmic contact layer 116 with insufficient reflectance (e.g. 90% or less) to improve the extraction efficiency.

The light-transmitting low refractive index layer 115 may be formed of a conductive or non-conductive material. For example, the light-transmitting low refractive index layer may be formed of indium tin oxide (ITO) as a conductive material. Also, the light-transmitting low refractive index layer may be formed of one selected from a group consisting of SiO₂, MgF₂, porous SiO₂, and MgO as a non-conductive material.

The high reflectivity ohmic contact layer 116 is connected to the second conductivity type nitride semiconductor layer 114 through the openings of the light-transmitting low refractive index layer 115, forming an ohmic contact with the second conductivity type nitride semiconductor layer 114 and effectively increasing the extraction efficiency by using high reflectance. The reference numeral 117 denotes a second electrode formed on a portion of the first conductivity type nitride semiconductor layer 112, exposed after mesa etching.

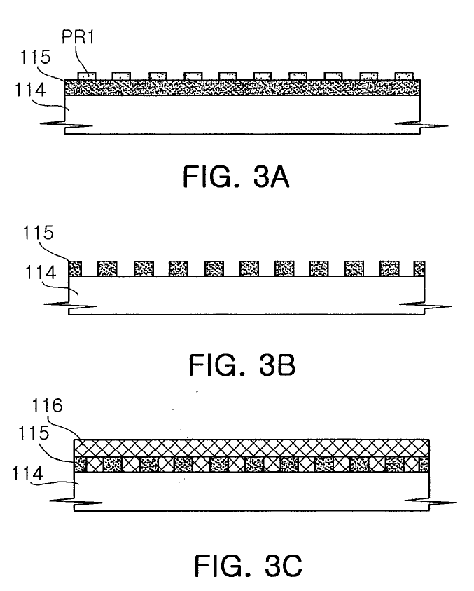

FIGS. 3A to 3C are views illustrating a method of manufacturing the nitride semiconductor light emitting device shown in the embodiment of FIG. 2.

For the sake of convenience in description, a process, after the first conductivity type nitride semiconductor layer 112, the active layer 113 and the second conductivity type nitride semiconductor layer 112 are sequentially formed on the substrate 111, will be described. In this case, the first and second conductivity type semiconductor layers 112 and 114 may be formed through a known process of nitride growth such as metal organic chemical vapor deposition (MOCVD) and molecular-beam epitaxy (MBE).

Then, as shown in FIG. 3A, the light-transmitting low refractive index layer 115 is formed on the second conductivity type nitride semiconductor layer 114, and a mask (PR) having a plurality of windows is provided on the light-transmitting low refractive index layer 115. The light-transmitting low refractive index layer 115 is formed of a material having a refractive index lower than a refractive index of the second conductivity type nitride semiconductor layer 114. Particularly, the light-transmitting low refractive index layer 115 may be formed or a material having a refractive index lower than a refractive index (2.5) of GaN, which is the most representative nitride layer, and higher than a refractive index of air.

As described hereinabove, for example, the light-transmitting low refractive index layer 115 may be formed of ITO as a conductive material. Also, the light-transmitting low refractive index layer 115 may be formed of one selected from a group consisting of SiO₂, MgF₂, porous SiO₂, and MgO as a non-conductive material.

Next, as shown in FIG. 3B, by using the mask (PR) having the plurality of windows, a plurality of openings are formed in the light-transmitting low refractive index layer 115 to partially expose the second conductivity type nitride semiconductor layer 114. The high reflectivity ohmic contact layer 116 may be formed of a material selected from a group consisting of Ag, Ni, Al, Ph, Pd, Ir, Ru, Mg, Zn, Pt, Au and a combination thereof.

Then, as shown in FIG. 3C, the high reflectivity ohmic contact layer 116 is formed such that it is connected to the second conductivity type nitride semiconductor layer 114 through the openings of the light-transmitting low refractive index layer 115.

Another aspect of the invention provides a method of improving extraction efficiency by using air, i.e., vacant structures, different from the above-described embodiments, in which the extraction efficiency is improved by employing a low refractive index material.

In detail, another aspect of the invention provides a nitride semiconductor light emitting device employing a plurality of vacant structures having a refractive index lower than a refractive index of the second conductivity type nitride semiconductor layer, the vacant structures formed at least one of inside the second conductivity type nitride semiconductor layer and between the high reflectivity ohmic contact layer and the second conductivity type nitride semiconductor layer, and a method of manufacturing the same.

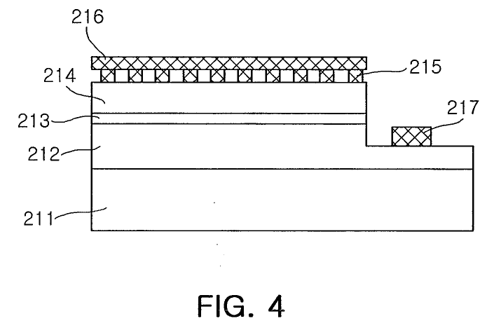

First, FIG. 4 is a side cross-sectional view illustrating a nitride semiconductor light emitting device according to another exemplary embodiment of the present invention, in which vacant structures are formed between the high reflectivity ohmic contact layer and the second conductivity type nitride semiconductor layer.

Referring to FIG. 4, the nitride semiconductor light emitting device includes a first conductivity type nitride semiconductor layer 212, an active layer 213 and a second conductivity type nitride semiconductor layer 214 sequentially formed on a substrate 211.

In addition, a conductive material layer 215, which is to be used as a part of an electrode, and a high reflectivity ohmic contact layer 216 are formed on the second conductivity type nitride semiconductor layer 214. The conductive material layer 215 has a plurality of openings through which the second conductivity type nitride semiconductor layer is partially exposed. The plurality of openings is provided as a desired plurality of vacant structures by the high reflectivity ohmic contact layer 216 formed on the conductive material layer 215. Since such vacant structures are hollow, i.e., filled with air, they may be expected to have a similar function as the low refractive index layer described with reference to FIG. 2.

That is, filled with air, the vacant structures have a large difference in refractive indices with GaN, thereby reflecting or changing the path of the light generated from the active layer and in turn effectively improving the extraction efficiency.

The conductive material layer 215 may be formed of a material enabling an ohmic contact with the second conductivity type nitride semiconductor layer 214, and may actually be formed of the same material as the high reflectivity ohmic contact layer 216.

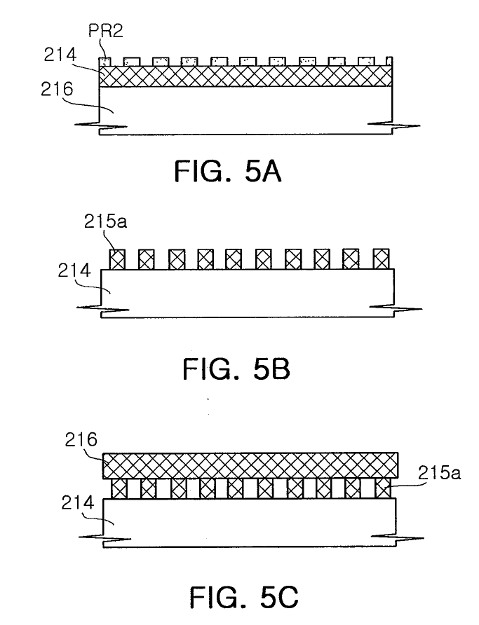

FIGS. 5A to 5C are views illustrating a method of manufacturing the nitride semiconductor light emitting device shown in the embodiment of FIG. 4.

As shown in FIG. 5A, the conductive material layer 215 is formed on the second conductivity type nitride semiconductor layer 214 and a mask (PR) having a plurality of windows is provided on the conductive material layer 216.

Next, as shown in FIG. 5B, the conductive material layer 215 is etched by using the mask (PR), and the mask (PR) is removed to provide the conductive material layer 215a having openings through which the second conductivity type nitride semiconductor layer 214 is partially exposed. The conductive material may be easily etched by a known wet etching process. The selectively etched conductive material layer 215a may be in a form of a mesh having a plurality of openings. Conversely, the conductive material layer 215a may be formed of a plurality of structures spaced apart.

As shown in FIG. 5C, the high reflectivity ohmic contact layer 216 is formed to retain the openings (or the spacing), thereby obtaining desired vacant structures. Since such vacant structures are hollow, i.e., filled with air and having a low refractive index, they may act as a low refractive index region, thereby improving the extraction efficiency.

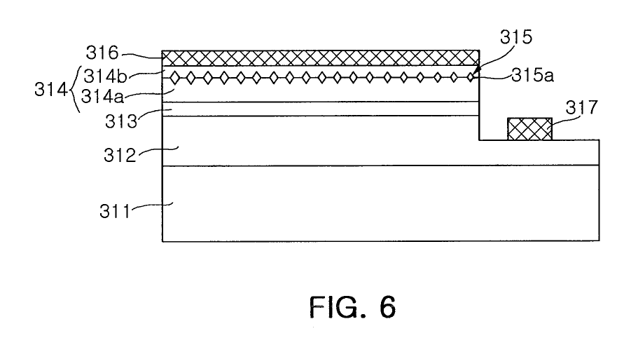

FIG. 6 is a side cross-sectional view illustrating a nitride semiconductor light emitting device according to further another embodiment of the present invention.

Referring to FIG. 6, the nitride semiconductor light emitting device according to this embodiment includes a first conductivity type nitride semiconductor layer 312, an active layer 313, a second conductivity type nitride semiconductor layer 314 sequentially formed on a substrate 311. First and second electrodes 316 and 317 are formed on the second conductivity type nitride semiconductor layer 314 and a mesa-etched portion of the first conductivity type nitride semiconductor layer 313, respectively, and the second electrode 316 is provided as a high reflectivity ohmic contact layer.

In this embodiment, vacant structures 315a are provided between a lower region 314a of the second conductivity type nitride semiconductor layer and an upper region 314b of the second conductivity type nitride semiconductor layer. The vacant structures 315a include a plurality of dispersed vacant spaces. Such vacant structures may be obtained by forming pits in the lower region 314a and re-growing the upper region 314b of the second conductivity type nitride semiconductor layer such that the pits are retained as vacant spaces.

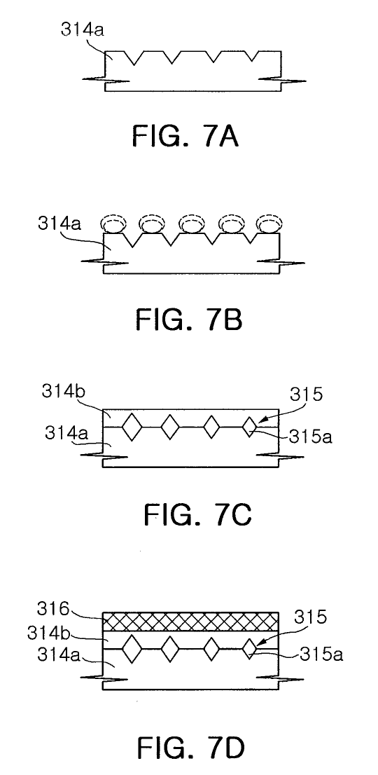

FIG. 7A to 7D are views illustrating a method of manufacturing the nitride semiconductor light emitting device shown in the embodiment of FIG. 6.

As shown in FIG. 7A, after the lower region 314a of the second conductivity type nitride semiconductor layer is formed, the pits are formed therein. The pits may be formed in an irregular arrangement by selectively etching the high-density defective regions. However, the present invention is not limited thereto, and a desired size and arrangement of the vacant spaces may be obtained by providing a mask on the lower region 314a of the second conductivity type nitride semiconductor layer, patterning exposed portions and performing selective etching by using the mask.

Then, as shown in FIG. 7B, second conductivity type nitride single crystals (indicated by dotted lines) are re-grown on the lower region of the second conductivity type nitride semiconductor layer in which the pits are formed. In this case, the re-growth starts from the adjacent areas of the pits while suitably applying a lateral growth mode to grow the upper region 314b such that the pits are retained as vacant spaces 315a.

Then, the high reflectivity ohmic contact layer 316 is formed on the re-grown second conductivity type nitride semiconductor layer 314b.

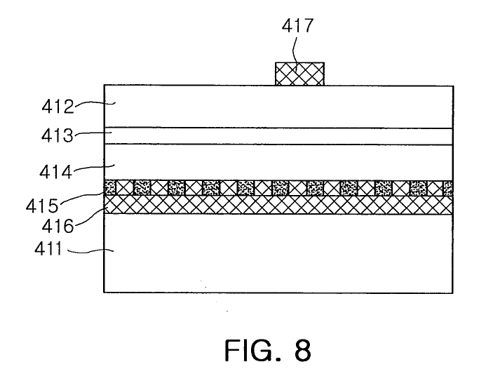

FIG. 8 is a side cross-sectional view illustrating a nitride semiconductor light emitting device according to still another embodiment of the present invention, showing that a vertical structure, in which a light-transmitting substrate is separated from a light emitting structure by for example emitting a laser beam or lapping, is also possible.

Referring to FIG. 8, the nitride semiconductor light emitting device includes a light emitting structure including a first conductivity type nitride semiconductor layer 412, an active layer 413, and a second conductivity type nitride semiconductor layer 414, and a conductive substrate 411, sequentially stacked. The light emitting device further includes a light-transmitting low refractive index layer 415 and a high reflectivity ohmic contact layer 416 between the light emitting structure and the conductive substrate, similar to the embodiment shown in FIG. 2.

In this structure, the light-transmitting low refractive index layer 415 is a low refractive index material layer formed of a material having a refractive index lower than a refractive index of the second conductivity type nitride semiconductor layer 414 and has a plurality of openings through which the second conductivity type nitride semiconductor layer 414 is partially exposed. In addition, the high reflectivity ohmic contact layer 416 is employed as a means to form an ohmic contact with the second conductivity type nitride semiconductor layer 414 and to increase the extraction efficiency as a reflecting structure. In addition, the light-transmitting low refractive index layer 415 is capable of reflecting the light before the light partially reaches the high reflectivity ohmic contact layer 416 from the active layer 413, by the difference in refractive indices with the nitride semiconductor layer, thereby compensating the high reflectivity ohmic contact layer 416 to improve the extraction efficiency.

The conductive substrate, serving as a supporting layer and an electrode of the final LED device, may be one of Si substrate, a GaAs substrate, a Ge substrate and a metallic layer. In this case, the metallic layer may be formed by a process such as electroplating, electroless plating, thermal evaporation, e-beam evaporation, sputtering, chemical vapor deposition and the like.

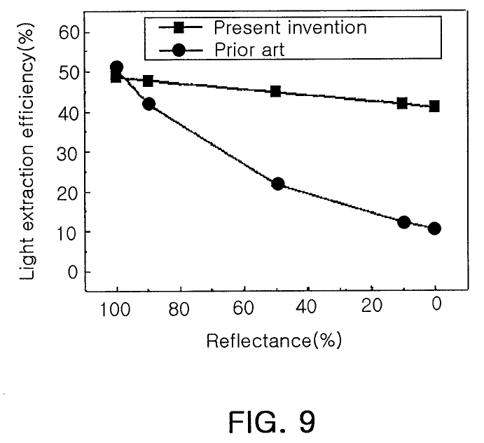

FIG. 9 is a graph comparing the extraction efficiency between the conventional light emitting device and the light emitting device according to the present invention.

Referring to FIG. 9, as the reflectance of the reflective layer (x-axis) decreases, the extraction efficiency of the light emitting device of the present invention (y-axis) decreases more gradually compared to the conventional light emitting device without an interlayer.

As described above, the present invention can minimize the effect of the reflective layer in a light emitting device employing a reflecting surface formed on an entire surface, resultantly effectively decreasing total internal reflection inside the chip, thereby improving the extraction efficiency to a maximum.

The present invention as set forth above provides an advantage of mitigating degradation of extraction efficiency due to the reflecting surface in a semiconductor light emitting device.

While the present invention has been shown and described in connection with the exemplary embodiments, it will be apparent to those skilled in the art that modifications and variations may be made without departing from the spirit and scope of the invention as defined by the appended claims.

1-10. (canceled)

11. A nitride semiconductor light emitting device comprising:
a first conductivity type nitride semiconductor layer formed on a substrate;
an active layer formed on the first conductivity type nitride semiconductor layer;
a second conductivity type nitride semiconductor layer formed on the active layer;
a high reflectivity ohmic contact layer formed on the second conductivity type nitride semiconductor layer; and
a plurality of vacant structures having a refractive index lower than a refractive index of the second conductivity type nitride semiconductor layer, and formed at least one of inside the second conductivity type nitride semiconductor layer and between the high reflectivity ohmic contact layer and the second conductivity type nitride semiconductor layer.

12. The device of claim 11, wherein the plurality of vacant structures are formed in an area between the high reflectivity ohmic contact layer and the second conductivity type nitride semiconductor layer.

13. The device of claim 12, further comprising a conductive material layer formed on the second conductivity type nitride semiconductor layer, between the high reflectivity ohmic contact layer and the second conductivity type nitride semiconductor layer, and having a plurality of openings,
wherein the plurality of openings are provided as the plurality of vacant structures by the high reflectivity ohmic contact layer formed on the conductive material layer.

14. The device of claim 11, wherein the plurality of vacant structures are formed inside the second conductivity type nitride semiconductor layer.

15. The device of claim 14, wherein the plurality of vacant structures are obtained by forming a plurality of pits in a lower region of the second conductivity type nitride semiconductor layer and re-growing an upper region of the second conductivity type semiconductor layer such that the pits are retained as the vacant structures.

16. The device of claim 11, wherein the high reflectivity ohmic contact layer is formed of a material selected from a group consisting of Ag, Ni, Al, Ph, Pd, Ir, Ru, Mg, Zn, Pt, Au and a combination thereof.

17. A method of manufacturing a nitride semiconductor light emitting device, the method comprising:
forming a first conductivity nitride semiconductor layer on a substrate;
forming an active layer on the first conductivity type nitride semiconductor layer;
forming a second conductivity type nitride semiconductor layer formed on the active layer;
forming a high reflectivity ohmic contact layer on the second conductivity nitride semiconductor layer; and
forming a plurality of vacant structures at least one of inside the second conductivity type nitride semiconductor layer and between the high reflectivity ohmic contact layer and the second conductivity type nitride semiconductor layer.

18. The method of claim 17, wherein the forming a plurality of vacant structures comprises forming the plurality of vacant structures in an area between the high reflectivity ohmic contact layer and the second conductivity type nitride semiconductor layer.

19. The method of claim 18, wherein the forming a plurality of vacant structures comprises:
forming a conductive material layer having a plurality of openings on the second conductivity type nitride semiconductor layer; and
forming the high reflectivity ohmic contact layer on the conductive material layer to retain the plurality of openings as the vacant structures.

20. The method of claim 17, wherein the forming a plurality of vacant structures comprises forming a plurality of vacant structures inside the second conductivity type nitride semiconductor layer.

21. The method of claim 20, wherein the forming a plurality of vacant structures comprises:
growing a lower region of the second conductivity type nitride semiconductor layer;
forming a plurality of pits in the lower region of the second conductivity type nitride semiconductor layer; and
re-growing an upper region of the second conductivity type nitride semiconductor layer on the lower region of the second conductivity type nitride semiconductor layer such that the pits are retained as vacant structures.

22. The method of claim 21, wherein the high reflectivity ohmic contact layer is formed of a material selected from a group consisting of Ag, Ni, Al, Ph, Pd, Ir, Ru, Mg, Zn, Pt, Au and a combination thereof.
